(19) United States
(12) Patent Application Publication
(10) Pub. No.: US 2013/0300401 A1
(43) Pub. Date: Nov. 14, 2013

(54) Sensor Apparatus, in Particular Metal Sensor, with a Field-Compensated Magnetic Field Sensor

(71) Applicants: Reiner Krapf, Filderstadt (DE); Tobias Zibold, Stuttgart (DE); Andrej Albrecht, Stuttgart (DE)

(72) Inventors: Reiner Krapf, Filderstadt (DE); Tobias Zibold, Stuttgart (DE); Andrej Albrecht, Stuttgart (DE)

(73) Assignee: Robert Bosch GmbH, Stuttgart (DE)

(21) Appl. No.: 13/881,659

(22) PCT Filed: Sep. 21, 2011
(86) PCT No.: PCT/EP2011/066378

§ 371 Date: Jul. 30, 2013

(30) Foreign Application Priority Data
Oct. 28, 2010 (DE) 10 2010 043 078.1

(51) Int. Cl. G01R 33/00

(52) U.S. Cl. CPC G01R 33/0005
USPC 324/201

(57) ABSTRACT

A sensor apparatus, in particular a metal sensor, has at least two coils and a magnetic field sensor. The arrangement of coils and magnetic sensor with respect to one another and/or the number of coil turns and/or the winding sense of the coils and/or the coil current is/are selected such that the magnetic field generated by the coils approximately disappears at the location of the magnetic field sensor. A method for detecting objects, in particular a method for finding metal objects, uses at least two coils and a magnetic field sensor, particularly an AMR, GMR or Hall sensor. The arrangement of the coils and the magnetic sensor with respect to one another and/or the number of coil turns and/or the winding sense of the coils and/or the coil current is/are selected such that the magnetic field generated by the coils approximately disappears at the location of the magnetic field sensor.

The invention relates to a sensor apparatus and to a method for locating objects enclosed in a medium, in particular metal objects, in accordance with the preamble of claim 1 and claim 15, respectively. Furthermore, the invention describes a tool, in particular a measuring instrument, for example a portable locator, with such a sensor apparatus for implementing the method as claimed in claim 15.

### PRIOR ART

In order to detect objects enclosed in a medium such as a wall, a ceiling or a floor, for example, such as electrical lines, water pipes, pipes, metal posts, for example, locators have been used for a relatively long period of time. Examples of devices used are inductive appliances, i.e. appliances which produce a magnetic field which is disrupted by metal objects enclosed in a medium.

Such a system is known from DE 10 2004 011 285 A1.

The prior art in the sector of metal sensors for locating metal objects, such as reinforcing iron bars, pipes or cables, for example, in walls or floors comprise coil-based metal sensors. There are various embodiments of such metal sensors: (i) field-compensated, (ii) differential, (iii) field-compensated and differential.

The object of the invention is to improve metal sensors for locating metal objects in walls and floors in terms of the aspect of miniaturization, integration and performance.

### DISCLOSURE OF THE INVENTION

A core concept of the invention comprises a metal sensor for locating metal objects in walls and floors which combines the advantages of field-compensated, differential, coil-based sensors and makes use of the additional advantages of special magnetic field sensors, in particular inexpensive Hall sensors, but also AMR/GMR-based magnetometers and SQUIDs (AMR sensor: anisotropic magnetoresistive sensor; GMR sensor: giant magnetoresistive sensor; SQUID: superconducting quantum interference device).

Advantages of these abovementioned magnetic field sensors are the compact size, a high level of sensitivity, in particular sensitivity to local changes in magnetic field instead of changes in the magnetic flux through relatively large areas. This results in direct advantages for the metal sensor: compact size since the sensors themselves are small and, for example, small (printed) coils are sufficient for producing sufficiently large fields (owing to the high degree of sensitivity), integration of a plurality of individual sensors, which results in advantageous properties such as the possibility of position/depth estimation up to an image resolution of the object to be detected.

In this regard, the invention proposes a system comprising transmission coils and magnetic field sensors. The sensor apparatus according to the invention for locating objects enclosed in a medium, in particular for detecting metal articles, has an arrangement with at least two coils and a magnetic field sensor, wherein the arrangement of coils and magnetic sensor in relation to one another and/or the number of coil turns and/or the winding sense of the coils and/or the coil current is/are selected in such a way that the magnetic field produced by the coils at the location of the magnetic field sensor approximately disappears.

An object in the region of the magnetic field produced by the coils (“primary field”) produces a “secondary field”. This secondary field can then be measured according to the invention by means of a magnetic field sensor. The compensation of the primary field which can be achieved in this arrangement at the location of the magnetic field sensor is very advantageous for the use of magnetic field sensors for detecting metal/magnetizable objects since excessively high magnetic fields would bring the magnetic field sensor out of its operating range. High magnetic fields are, however, necessary in the case of the measurement in order to produce sufficiently high magnetic fields at the location of the object such that the resultant secondary fields at the location of the sensor are still sufficiently high. The apparatus according to the invention advantageously makes it possible to minimize the primary field or even to cause it to disappear, but with the secondary field of an object to be detected which is induced by the primary field being high enough to be detected by a magnetic field sensor.

A further advantage of the compensation of the primary field consists in that the ratio of the object-related signal (signal resulting from the secondary field) to the basic signal (signal resulting from the primary field) is improved by several orders of magnitude.

The described system comprising transmission coils and magnetic field sensor can in this case advantageously be realized with actuation in accordance with the push-pull controller principle. Advantages of the push-pull controller are in this case the high dynamics over a large field area and the high signal-to-noise ratio owing to the advantageous use of a synchronous demodulator.

When using printed coils, the secondary fields are very small (typically a few 10 nT). Therefore, in particular the highly sensitive AMR/GMR magnetic sensors are suitable for such an embodiment, while Hall sensors are in this case less suitable.

The use of periodic excitation fields is advantageous since the object-related component of the reception signal can then be isolated very well from interference and noise owing to its frequency (for example using a synchronous demodulator).

Further advantages of the sensor apparatus according to the invention are given in the dependent claims, the exemplary embodiment below and the drawings and associated descriptions.

### DRAWING

The drawing illustrates an exemplary embodiment of the sensor apparatus according to the invention which will be explained in more detail in the description below. The figures in the drawing, the description thereof and the claims contain numerous features in combination. A person skilled in the art will also consider these features individually and combine them to produce other or further expedient combinations.

In the drawing:

FIG. 1 shows a typical arrangement of a sensor apparatus according to the invention in a very schematized illustration,

FIGS. 2a show the calculated magnetic field of and 2b two coils of the sensor apparatus in a graphical representation,

FIGS. 3a show the calculated magnetic field of and 3b the coils of the sensor apparatus according to the invention in two orthogonal directions,

FIGS. 4a show the calculated z component of the and 4b primary magnetic field of two coils of the sensor apparatus and the secondary magnetic field produced by an object in an overview representation (2a) and in a detail representation (2b),

FIG. 5 shows the actuation of the sensor apparatus according to the invention by means of a push-pull controller,

FIG. 6 shows an exemplary embodiment of a tool according to the invention in the form of a locator.

### DESCRIPTION OF AN EXEMPLARY EMBODIMENT

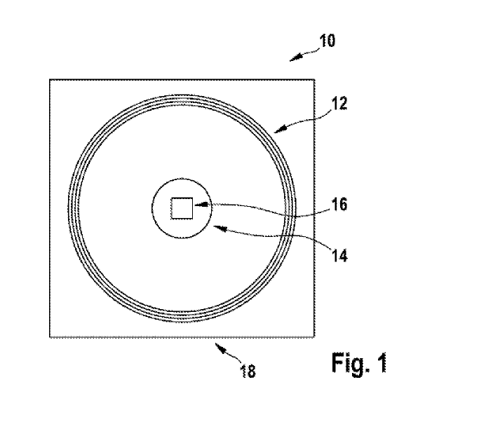

FIG. 1 shows a possible embodiment of a sensor apparatus 10 according to the invention in a schematized illustration.

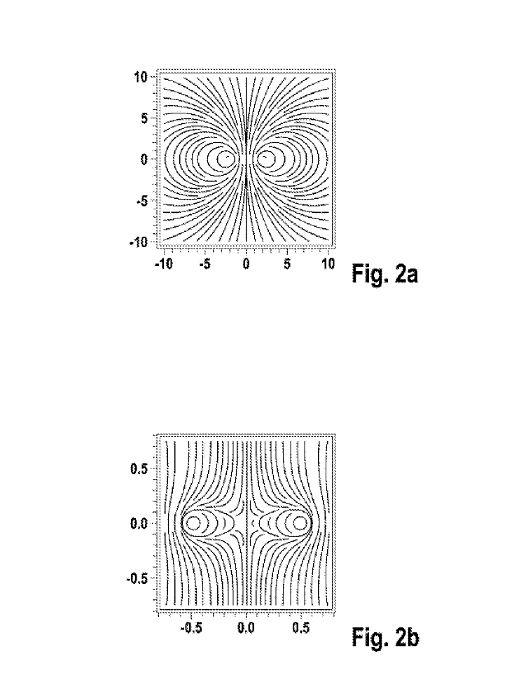

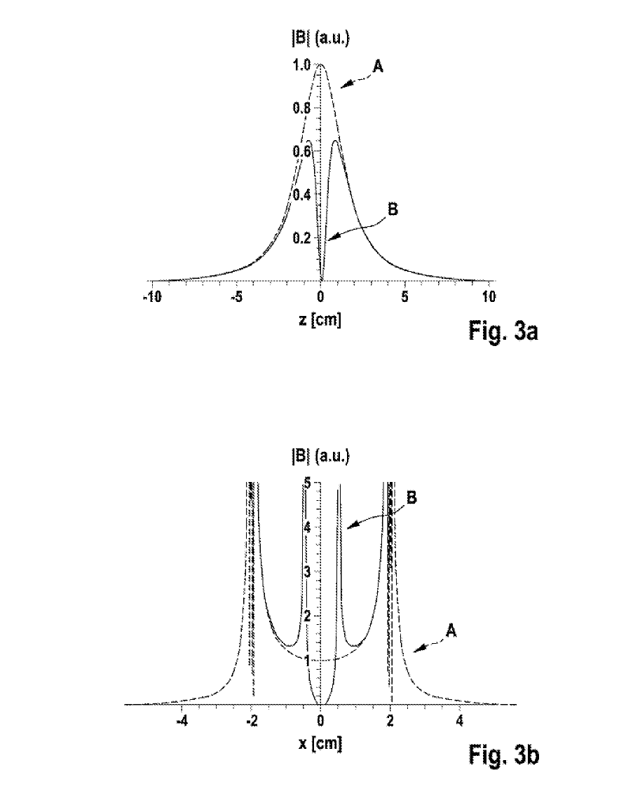

The arrangement shown by way of example in FIG. 1 of a sensor apparatus according to the invention has two coils (“outer coil 12” “inner coil 14”), which are used to produce, in space, a periodically changing, quasi-stationary magnetic field (in this case in particular a dipole field) (see also FIGS. 2, for example, in this regard). A magnetic field sensor 16 which can be in the form of a Hall sensor, an AMR or else GMR sensor or else in the form of a SQUID, for example, is used to measure a magnetic field which is produced in particular by an object to be detected. The arrangement of the coils and the sensor in relation to one another, and the number of turns, the winding sense, and the coil current of the coils are in this case selected in accordance with the invention in such a way that the magnetic field produced by the coils at the location of the magnetic field sensor (and ideally only there) approximately (and ideally exactly) disappears, i.e. becomes zero, i.e. field compensation takes place at the location of the magnetic field sensor (see in this regard, for example, also the calculated fields in FIG. 3). Ideal field compensation, in which the magnetic field of the coils becomes zero in the mathematical sense, cannot really be realized from a practical point of view. This is intended to be encompassed by the term “disappears approximately”. The rest and so-called “dirt effect” which in the final analysis, prevent the absolute elimination of the magnetic field, fall under the approximate compensation.

The two coils 12, 14 of the sensor apparatus in the exemplary embodiment in FIG. 1 are formed concentrically to one another in a common plane, in particular on a common printed circuit board 18.

For two concentric coils arranged in one plane with opposing winding sense, the magnetic field at the center point of the two coils disappears, when the same current is flowing through both of said coils, under the following condition:

N/d=N′/d′ (I)

N: number of turns of the outer coil, d: diameter of the outer coil,

N′: number of turns of the inner coil, d′: diameter of the inner coil.

Strictly speaking, the coil diameter must be large in comparison with the distance between the individual coil turns in the coil for the above relationship (I).

One advantage of the use of two coils with opposite winding sense is in particular that the coils can be connected in series.

In the exemplary embodiment in FIG. 1, the coils are in the form of printed coils on the printed circuit board 18. In alternative embodiments, conventional coils, even more than two coils and in particular also coils which are not arranged concentrically can also be used.

It is also possible for the transmission coils to be located next to one another and/or to overlap one another, for example. However, a core concept of the invention consists in always fitting the magnetic field sensor in a region with a disappearing coil magnetic field.

Given a suitable coil arrangement, numbers of turns and winding sense, it is possible to connect the coils electrically in series. The same current then flows through said coils and changes in this current which are produced, for example, by temperature or else other environmental influences, advantageously do not have an effect on the field compensation at the location of the magnetic field sensor.

A magnetic field sensor 16 in the embodiment of a GMR sensor is arranged in the center, i.e. at the center point of the circular coils 12, 14, in the exemplary embodiment shown in FIG. 1. Alternative magnetic field sensors are likewise possible, however.

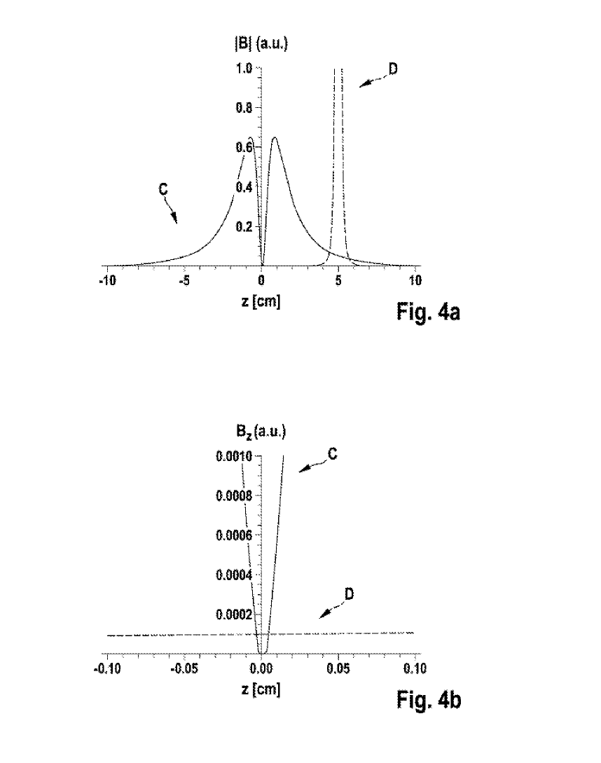

An object in the region of the magnetic field produced by the coils 12, 14 (“primary field”) produces a “secondary field”. This secondary field is then measured by the magnetic field sensor 16 in accordance with the invention. In this way, an object can be detected (cf. in this regard also FIG. 4).

The preferential direction of the sensor, i.e. the direction with respect to which magnetic fields need to be parallel in order to be measured by the sensor with maximum sensitivity, should point in the normal direction of the coil plane in the case of a planar, concentric coil arrangement with magnetic field sensor in the center of the coil, as illustrated in FIG. 1.

The compensation of the primary field at the location of the magnetic field sensor 16 is advantageous for the use of a magnetic field sensor in this application (detection of metal/magnetizable objects) since excessively high magnetic fields bring the sensor 16 out of its operating range. High magnetic fields are necessary, however, for producing sufficiently high magnetic fields at the location of the object such that the resultant secondary fields are still sufficiently high at the location of the sensor 16. A further advantage of the compensation of the primary field is that the ratio of the object-related signal (signal resulting from the secondary field) to the basic signal (signal resulting from the primary field) is improved by several orders of magnitude.

In the case of the optimization of the diameters of the coils of the sensor arrangement according to the invention, two opposite effects need to be taken into consideration:

(1) The dipole character of the total field is more pronounced when the inner coil has a diameter which is as small as possible in comparison with the outer coil.

The diameter of the inner coil is in this case substantially limited by the size of the magnetic field sensor and is therefore at a minimum value of approximately 5 mm.

(2) However, the magnetic field gradient in the region of the zero point of the field is lower the less the ratio of the coil diameters differs from the value one. This reduces the requirements placed on the positioning accuracy of the magnetic field sensor.

FIGS. 2a and 2b show the calculated magnetic field of two printed coils (outer coil with 4 turns, radius 2 cm, inner coil with one turn, radius 0.5 cm) in the x-z plane. The magnetic field is rotationally symmetrical about the z axis. FIG. 2a shown on the left shows the dipole field in the outer region, and FIG. 2b on the right shows the compensation of the fields produced by the two coils in the region of the inner coil.

In addition to the dipole arrangements described here, quadrupole arrangements are also conceivable, which function on the basis of the same principle.

FIGS. 3a and 3b show calculated absolute values of the magnetic field of the outer coil (A) and of the outer and inner coil (B). The curves show that the magnetic field of the outer and inner coil disappear together at the origin (so-called “field compensation”). The field in the outer region is virtually uninfluenced by the compensation. This is important for ensuring the same sensor range which would be achieved without the additional compensation coil in the form of the inner coil.

FIG. 4 shows the z component of the primary magnetic field (C) and the secondary magnetic field (D) along the z axis (FIG. 4 represents a detail in the direct vicinity of the zero point; cf. in this regard the respective scales). The source of the secondary field in this simulation is an iron ball (with a relative magnetic permeability μ=1000 and a diameter 1 cm), which is located at a distance of 5 cm from the sensor on the z axis. The case for low frequencies of the excitation field (Ω→0) is calculated. It should be noted that, without the inner compensation coil, the sensor field at the origin/zero point would have the value 1, i.e. would be a factor of 10 000 greater than the object field.

The described system comprising transmission coils and magnetic field sensor can be actuated very well and advantageously with a push-pull controller 20. Advantages of the push-pull controller are the high dynamics over a large field region and the high signal-to-noise ratio owing to the use of a synchronous demodulator.

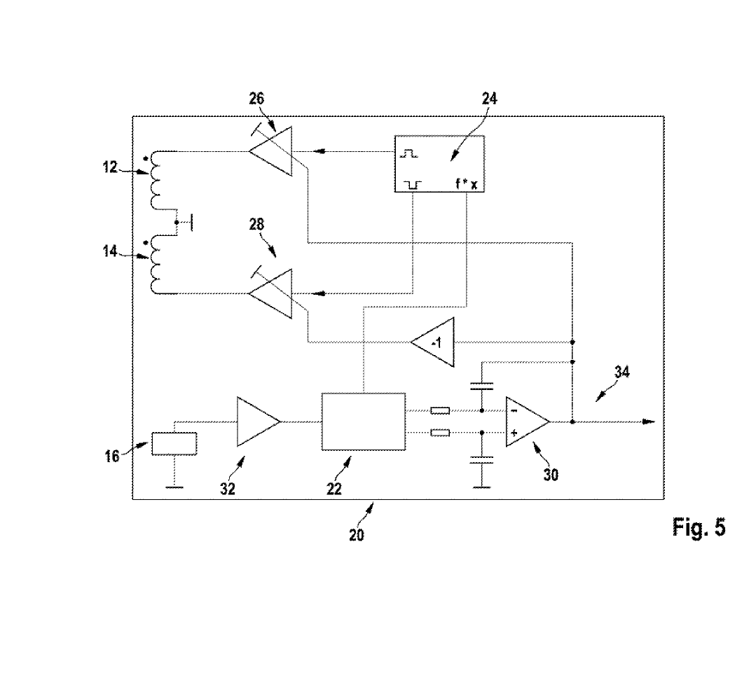

FIG. 5 shows exemplary circuitry for the coils and the magnetic sensor in the push-pull mode.

The push-pull controller 20 comprises, in the embodiment shown in FIG. 5, a signal source 24, controllable amplifiers 26, 28, a synchronous demodulator 22 and an integrating comparator 30. The controllable amplifiers 26, 28 energize the two transmission coils 12, 14 with periodically changing currents of independent amplitude which are phase-shifted through 180°. The transmission coils (for example outer and inner coils corresponding to FIG. 1) are now wound in such a way that, at least in the absence of metal/magnetizable objects in the region of the transmission coil field, they produce oppositely directed magnetic fields, at least at a point in time, which oppositely directed magnetic fields cancel one another out at the location of the sensor. The sensor 16 is possibly connected to the synchronous demodulator 22 via an optional amplifier 32. The push-pull control via the integrating comparator 30 regulates the amplitudes of the transmission coil currents by means of the controllable amplifiers 26, 28 in such a way that, even in the presence of a metal/magnetizable object in the region of the transmission coil field at least at a point in time, the magnetic field disappears at the location of the sensor. This controlled value changes in the case of the presence of a metal/magnetizable object and can therefore be used to detect such an object.

In addition to the system shown here of a sensor apparatus with two coils and a magnetic field sensor, however, systems with more than two coils and/or a plurality of magnetic field sensors are also conceivable and also expedient.

Thus, in particular also the use of a plurality of “compensation coils” (in the exemplary embodiment of the inner coil 14 for canceling the primary field) at different locations is possible. In this case, sensor systems in which the positions of the plurality of compensation coils are arranged both inside and outside the “outer” transmission coil are possible.

It may also be advantageous to arrange the transmission coils in different planes.

The use of a plurality of magnetic field sensors at in each case those locations which are kept field-free by the respective compensation coil is also an advantageous variant of the sensor apparatus according to the invention. It is advantageous that the secondary field (i.e. the field produced by an object to be measured) can be measured at different locations and therefore at least in principle conclusions can be drawn on object properties, such as the lateral position, the embedding depth or else the orientation, for example.

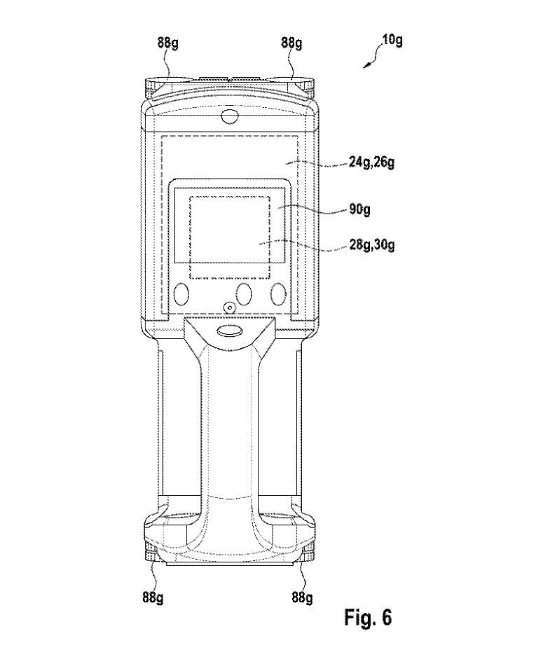

FIG. 6 shows a possibility of an exemplary embodiment of a tool according to the invention in the form of a measuring instrument, in the form of a portable locator 86g, which has a sensor apparatus according to the invention. The portable locator 86g has a locating apparatus 24g with a sensor apparatus 26g according to the invention. In the manner already described, the sensor apparatus 26g comprises at least two coils and at least one magnetic field sensor, which are arranged in accordance with the invention and operate in accordance with the method according to the invention. The locating apparatus 24g comprises, furthermore, an actuating unit 28g, in particular with a push-pull controller 20, and an evaluation unit 30g for processing and conditioning the measured signals. Thus, in particular the controlled signal 32 of the push-pull controller 20 (see also FIG. 5 in this regard) can be used by the evaluation unit 30g in order to characterize an object as detected or not detected. This means that the controlled signal 32 of the push-pull controller of the sensor apparatus according to the invention is used for detection of the objects.

The portable locator 86g also has rollers 88g with distance measurement means (not illustrated in any more detail), by means of which an operator can move the portable locator 86g along the medium. The portable locator 86g represents detected objects depending on the distance travelled on a display 90g of the portable locator 86g. The distance sensor system makes it possible to assign a detection value of the sensor apparatus according to the invention to a location of the measuring instrument. In particular, the measuring instrument according to the invention enables the correlated representation of detection signal and position of embedded objects via a corresponding output unit 90g, in particular a graphical display. In relatively simple embodiments, the distance sensor system can also be dispensed with, and the detection of an object can be transmitted merely by a light signal and/or an acoustic signal, for example.

The method according to the invention or a tool operating in accordance with this method is not restricted to the exemplary embodiments illustrated in the figures.

In particular, the method according to the invention is not restricted to the use of two transmission coils, in particular two concentrically arranged transmission coils. It is thus also possible for the transmission coils to be located next to one another and/or to overlap one another, for example. A core concept of the invention consists in fitting the magnetic field sensor in a region with a disappearing coil magnetic field.

In addition to the system shown here with two coils, however, systems with more than two coils are also conceivable and also expedient.

Thus, in particular also the use of a plurality of “compensation coils” (inner coils) at different locations is possible. In this case, sensor systems in which the positions of the several compensation coils are arranged both inside and outside the “outer” transmission coil are possible.

It may also be advantageous to arrange the transmission coils in different planes.

The use of a plurality of magnetic field sensors at in each case the locations which are kept field-free by the respective compensation coil is also an advantageous variant of the sensor apparatus according to the invention. One advantage with this is that the secondary field (i.e. the field produced by an object to be measured) can be measured at different locations and therefore, at least in principle, conclusions can be drawn on object properties, such as the lateral position, the embedding depth or else the orientation, for example.

The magnetic field could also be brought to zero by a shielding apparatus, and the magnetic sensor fitted at a corresponding location.

The tool according to the invention is not restricted to a measuring instrument, in particular a locator. Sawing, grinding or drilling tools can also be equipped with the sensor apparatus according to the invention, whether it be as a measurement system integrated in the tool or else also as an accessory to be attached to the tool.

1. A sensor apparatus, comprising:
at least two coils; and
a magnetic field sensor,
wherein at least one of (i) an arrangement of the at least two coils and magnetic sensor in relation to one another, (ii) a number of coil turns, (iii) a winding sense of the at least two coils, and (iv) a coil current is configured such that a magnetic field produced by the at least two coils at a location of the magnetic field sensor approximately disappears.

2. The sensor apparatus as claimed in claim 1, characterized in that wherein:
the at least two coils includes a first, outer coil and a second, inner coil, and
the first, outer coil and the second, inner coil are positioned concentrically with respect to one another.

3. The sensor apparatus as claimed in claim 1, wherein the magnetic field sensor is surrounded by turns of at least one coil of the at least two coils.

4. The sensor apparatus as claimed in claim 1, wherein the magnetic field sensor is positioned at a center point of at least one substantially circular coil of the at least two coils.

5. The sensor apparatus as claimed in claim 1, wherein the at least two coils and the magnetic field sensor are positioned in a common plane.

6. The sensor apparatus as claimed in claim 1, wherein the at least two coils and the magnetic field sensor are supported on a common printed circuit board.

7. The sensor apparatus as claimed in claim 1, wherein at least one coil of the at least two coils includes a printed coil.

8. The sensor apparatus as claimed in claim 6, wherein the magnetic field sensor includes an anisotropic magnetoresistive sensor.

9. The sensor apparatus as claimed in claim 1, wherein the magnetic field sensor includes a giant magnetoresistive sensor.

10. The sensor apparatus as claimed in claim 1, wherein the magnetic field sensor includes a Hall sensor.

11. The sensor apparatus as claimed in claim 1, wherein the magnetic field sensor includes a superconducting quantum interference device.

12. The sensor apparatus as claimed in claim 1, wherein the at least two coils are connected electrically in series.

13. The sensor apparatus as claimed in claim 1, further comprising:
a push-pull controller configured to actuate the at least two coils.

14. A tool comprising:
at least one sensor apparatus including at least two coils and a magnetic field sensor,
wherein at least one of (i) an arrangement of the at least two coils and magnetic sensor in relation to one another, (ii) a number of coil turns, (iii) a winding sense of the at least two coils, and (iv) a coil current is configured such that a magnetic field produced by the at least two coils at a location of the magnetic field sensor approximately disappears.

15. A method for detecting objects using at least two coils and a magnetic field sensor comprising:
configuring at least one of (i) an arrangement of the at least two coils and the magnetic sensor in relation to one another, (ii) a the number of coil turns, (iii) a winding sense of the coils, and (iv) a coil current such a that the magnetic field produced by the at least two coils at the a location of the magnetic field sensor approximately disappears.

16. The method as claimed in claim 15, further comprising:
regulating amplitudes of the coil currents of the at least two coils with a push-pull controller using controllable amplifiers such that the magnetic field disappears at the location of the magnetic sensor, at least at a point in time.

17. The method as claimed in claim 16, further comprising:
using a controlled value of the push-pull controller to detect an object.

18. The sensor apparatus as claimed in claim 1, wherein the at least one of (i) the arrangement of the at least two coils and magnetic sensor in relation to one another, (ii) the number of coil turns, (iii) the winding sense of the at least two coils, and (iv) the coil current is configured such that the magnetic field produced by the at least two coils at the location of the magnetic field sensor is completely compensated for.

19. The method as claimed in claim 15, wherein the magnetic field sensor is selected from the group consisting of an anisotropic magnetoresistive sensor, a giant magnetoresistive sensor, and a Hall sensor.

20. The method as claimed in claim 15, further comprising:
configuring the at least one of (i) the arrangement of the at least two coils and the magnetic sensor in relation to one another, (ii) the number of coil turns, (iii) the winding sense of the coils, and (iv) the coil current such that the magnetic field produced by the at least two coils at the location of the magnetic field sensor is completely compensated for.
